(19) United States
(12) Patent Application Publication
(10) Pub. No.: US 2008/0286958 A1
(43) Pub. Date: Nov. 20, 2008

(54) Semiconductor Substrate Having Enhanced Adhesion And Method For Manufacturing The Same

(76) Inventors: Chien-Wei Chang, Taoyuan (TW); Cheng-Kuo Ma, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 12/185,817

(22) Filed: Aug. 5, 2008

Related U.S. Application Data
(62) Division of application No. 11/670,962, filed on Feb. 3, 2007.

(51) Int. Cl. H01L 21/44

(52) U.S. Cl. 438/612; 257/E21.476

(57) ABSTRACT

A semiconductor substrate for having enhanced adhesion to semiconductor device and its manufacturing method are provided. The wire circuit layout on the surface of the semiconductor substrate is of a specialized design and surface treatment for enhanced adhesion between the packaged adhered material and the substrate surface (the bonding pad in particular). In the manufacturing method of the semiconductor substrate, the processing by the passivation treatment or the roughening treatment of the whole or a part of the bonding pad on the substrate, such as the brown-oxide treatment or the black-oxide treatment, etc, and the use of an enlarged contact area act to enhance adhesion to the semiconductor device during the packaging of the semiconductor device.

### CROSS-REFERENCES TO RELATED APPLICATIONS

This is a division of U.S. application Ser. No. 11/670,962, filed Feb. 3, 2007, which is incorporated herewith by reference.

### BACKGROUND OF THE INVENTION

1. Field of the Invention

The present invention relates generally to a semiconductor substrate and its manufacturing method, and in particular to a semiconductor substrate having enhanced adhesion to the semiconductor devices, and its manufacturing method.

2. The Prior Arts

With the rapid development in the semiconductor manufacturing technology, the magnitude of the IC has evolved into the ultra large scale integration (ULSI) era.

Along with the coming of the ultra large scale integration (ULSI), due to meeting the requirements of the IC device miniaturization trend, the persistent growth in the quantity of the input/output (I/O), the much increased device integration have placed increasingly stricter requirements in thermal dissipation capabilities and efficiency, etc, electronic packaging technology has to develop in a direction towards improved packaging density, reduced packaging size, shortened transmission distance, reduced transmission delay, and increased control capability of the high-frequency interference signals.

The packaging types, apart from the earliest developed dual in line package (DIP), further includes chip carrier, flip chip (FC), pin grid array (PGA), tape carrier, hermetic package, ball grid array (BGA), quad flat package (QFP), lead on chip (LOC), chip scale package (CSP), bare die, tape carrier package (TCP).

With respect to the manufacturers of the computer chipset, the chipset packaging has underwent changes in the recent years, from the combination of QFP100 and QFP208 in the early days to be simplified to be of two chips, the South Bridge chip and the North Bridge chip. The packaging format has to be elevated to use BGA having more than 300 pins and another BGA having more than 500 pins, for meeting the functional and higher-densisty requirements. If the graphics chip is to be integrated in the future, the chipset of the future thus requires using the BGA having above 600 pins for performing packaging.

Referring to FIG. 1, FIG. 1 is a structural schematic view showing a conventional flip chip substrate. As shown in FIG. 1, the internal wire configurations have been arranged in the substrate 10 (not shown). On the surface of the substrate 10, the wire bonding pad 16 which electrically connects with the internal wire configurations (the wire bonding pad 16 is covered by the gold electroplating 18 for protection), the wires 20 which electrically connect with the electrical nodes (not shown) of the semiconductor device 24 and the wire bonding pad 16, and the bonding pad 12 which is used to adhere to the semiconductor device 24 are included (the bonding pad 12 is covered by the solder mask 14 for the prevention of Cu-oxidation). When the semiconductor device 24 is packaged onto the substrate 10, the semiconductor device 24 can adhere to the bonding pad 12 using the adhesive 22 so as to complete the electrical connection procedure of the wires 20 (the wire bonding process).

Referring to FIG. 2, FIG. 2 is another structural schematic view showing a conventional flip chip substrate. As shown in FIG. 2, the wire bonding pad 16 (covered by the gold electroplating 18 for protection), the wires 20, and the bonding pad 12 are also included on the surface of the substrate 10. The bonding pad 12 is additionally covered by the gold electroplating 18 for preventing Cu-oxidation. Similarly, when the semiconductor device 24 is packaged on the substrate 10, the semiconductor device 24 can adhere to the bonding pad 12 using the adhesive 22 for completing the electrical connection process of the wires 20 (the wire bonding process).

However, no matter whether the solder mask 14 covered on the bonding pad 12 as shown in FIG. 1 or the gold electroplating 18 covered on the bonding pad 12 as shown in FIG. 2, the surfaces of either of them are of inadequate adhesion capability. The gold electroplating 18 is especially the worst (since the organic adhesive 22 can not adequately adhere to the gold surface). After the performing of reliability experiments (TCT, PCT), delamination or peeling phenomena will often occur between the adhesive 22 and the solder mask 14, or between the adhesive 22 and the gold electroplating 18, which thereby affecting the product quality.

### SUMMARY OF THE INVENTION

A primary objective of the present invention is to provide a semiconductor substrate having enhanced adhesion to semiconductor device and its manufacturing method. The surface layout of the substrate is of a specialized design and surface treatment, whose gold surface is replaced by copper, and is processed by brown-oxide treatment or the black-oxide treatment for preventing the re-oxidation of the copper surface and raising the surface roughness of the substrate so as to enhance adhesion between the packaging adhered materials and the surface of the substrate (especially the bonding pad).

Based on this objective in this present invention, the surface layout on the surface of the substrate has been of a specialized design and surface treatment, which can enhance the adhesion between the packaged adhered materials and the surface of the substrate. In more further details, on the surface of the substrate, a whole or a portion of the entire region which are required to be adhered to the packaged material are to have an exposed copper surface area. However, in order to enhance adhesion, the exposed copper surface area above needs to be processed by passivation treatment or roughening treatment such as the brown-oxide treatment or the black-oxide treatment, etc, and/or the region processed by the passivation treatment then is processed by gold electroplating for enhancing conductivity. The manufacturing method of the semiconductor substrate is also disclosed in this present invention. The wire circuit layout on the surface of the substrate is processed by the final etching, while part of the copper surface is kept free from etching and is exposed. Then the whole or part of the aforementioned reserved exposed copper surface is processed by the passivation treatment or the roughening treatment such as the brown-oxide treatment or the black-oxide treatment, etc, and/or the region process by the passivation treatment is processed by gold electroplating.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a structural schematic view showing a conventional flip chip substrate;

FIG. 2 is another structural schematic view showing a conventional flip chip substrate;

FIG. 3 is a schematic view showing a semiconductor substrate having enhanced adhesion to a semiconductor device according to the present invention; and

FIG. 4 is another schematic view showing the semiconductor substrate having enhanced adhesion to the semiconductor device according to the present invention.

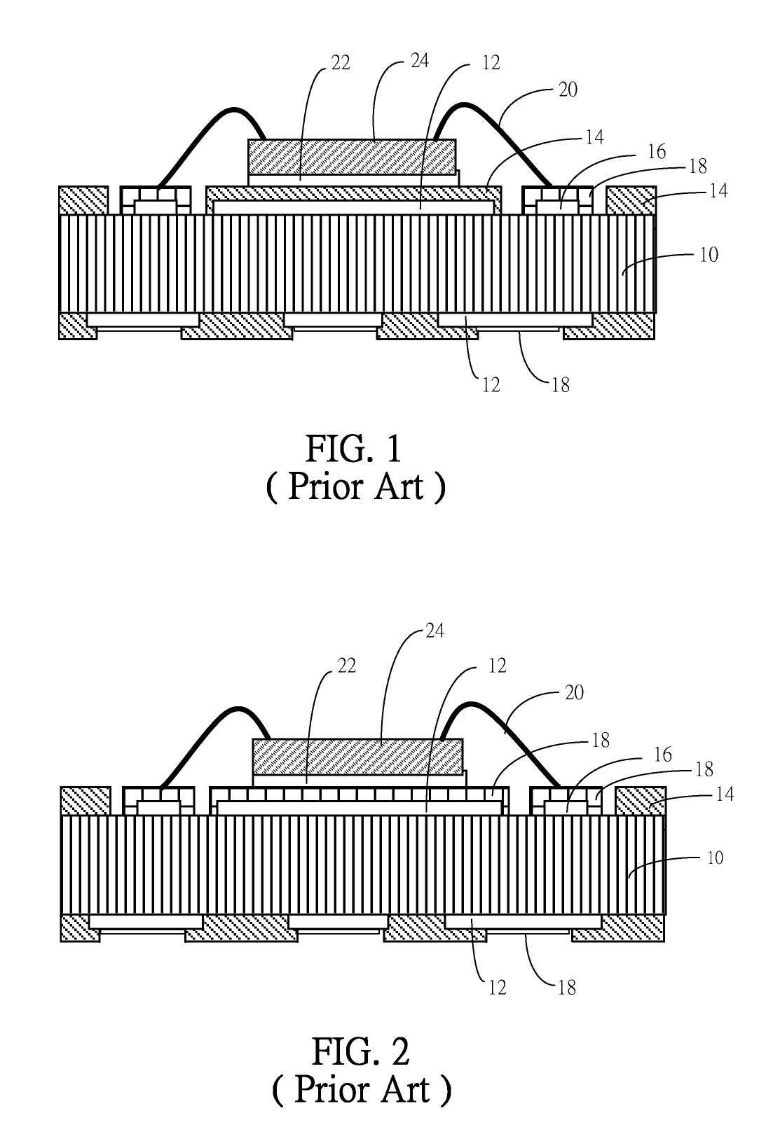

### DETAILED DESCRIPTION OF THE PREFERRED EMBODIMENT

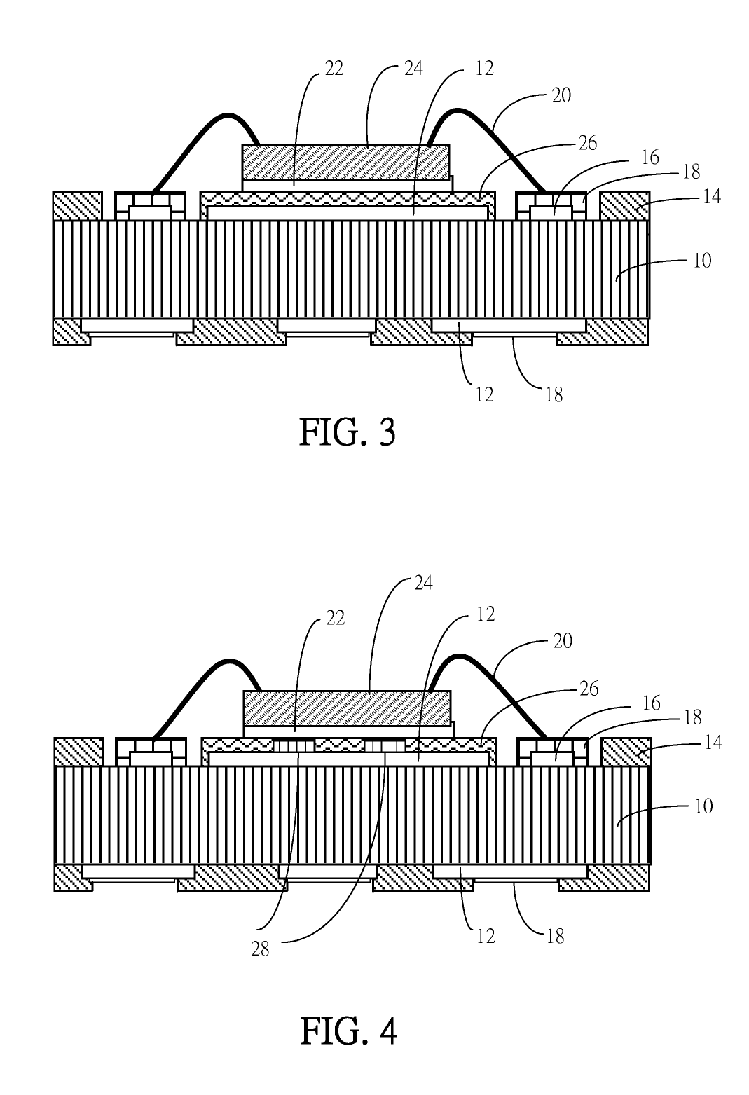

With reference to FIG. 3, FIG. 3 is a schematic view of a semiconductor substrate having enhanced adhesion to a semiconductor device according to the present invention. As shown in FIG. 3, a wire bonding pad 16 (covered by a gold electroplating 18 for protection), a wire 20, and a bonding pad 12 are included on the surface of a substrate 10. In the same manner, when a semiconductor device 24 (such as a chip) is packaged on the substrate 10, the semiconductor device 24 can adhere to the bonding pad 12 using an adhesive 22 for completing the electrical connection process of the wires 20 (wire bonding process).

In particularly, in order to prevent the delamination or peeling phenomena, and also to consider the prevention of the copper bonding pad 12 to be oxidized, the surface of the bonding pad 12 should be processed by the roughening treatment or passivation treatment firstly so as to form the roughened layer 26 (or the passivation layer). Thus, the bonding pad 12 which is coupled to the roughened layer 26 (or the passivation layer) and having also increased surface area is to be able to adhere to the semiconductor device 24 using the adhesive 22 to achieve a stronger bonding between the adhesive 22 and the bonding pad 12 than before, so as to ensure the product reliability and quality. More importantly, the whole or part of the bonding pad 12 is processed by the roughening treatment or the passivation treatment. Therein, the concurrent passivation treatment can be in the form of brown-oxide, red-oxide, or black-oxide treatment. Then the bonding pad 12 which has already been processed by the brown-oxide treatment or the black-oxide treatment can further be processed by the plasma treatment. The roughness of the surface of the bonding pad 12 which has underwent roughening or passivation treatment is 0.4 to 0.5 μm.

The parameters found in the aforementioned black-oxide process includes the following: the etching thickness, the immersion temperature, the AB concentration after the black-oxide treatment, the proportional amount of the AB solution, the treatment duration of the AB solution, and the ageing condition of the bath fluids of the AB solution, etc. The thickness of the black-oxide treatment can be controlled by performing analysis of the bath fluids and the measurement on the etching thickness. As the immersion temperature before the black-oxide treatment can be increased to about 30 to 40 centigrade degrees, the corresponding treatment time is 1 to 2 minutes, but can not be under room-temperature. This change can effectively ensure the uniformity of the surface color of the bonding pad treated by the black-oxide treatment so as to reduce the color difference caused by the nonuniformity of the surface color of the bonding pad treated by the black-oxide treatment. The differences in the proportional amount and the concentration of the black-oxide fluids affect the densely packing of the black-oxide layer and the uniformity of the surface color. While the treatment duration of the bath fluids and the ageing condition of the bath fluids affect the length of the black-oxide crystal and the physical behavoir of the crystallization layer. The black-oxide layer is an acicular crystal layer, and so if the treatment duration of the black-oxide treatment is too short so that the length of the crystallization layer is also short so as to be difficult to adhere to the adhesive 22 more tightly. However, if the treatment duration of the black-oxide treatment is too long, the acicular crystallization layer becomes too long and becomes more brittle so as the adhesive 22 is harder to infiltrate, which thereby affecting adhesion. After the bath fluids has undergone ageing, the black-oxide layer, which is one of a acicular crystallization layer, is changed to be longer and more brittle, and is even changed to be a powdery surface, so as to affect the adhesion of the bonding pad also after the semiconductor device 24 is packaged, and sometimes the Cu surface could also be exposed after combining part of the bonding pad 12. It is because, under high-pressure, the black-oxide layer is overflowed and disappeared, along with the adhesive and the volatile gas molecules together, when breaking off and sever from the Cu surface.

In generally, the black-oxide layer includes much more of the Cu⁺ elements, and the brown-oxide layer includes much more of the Cu⁺⁺ elements, and thus of higher stability. But the black-oxide treatment and the brown-oxide treatment both take place in the bath fluids at high temperatures (80 to 90° C.) for 3 to 5 minutes. These two treatment processes are not convenient, and the dimensions of the black-oxide layer or the brown-oxide layer have the tendency to drift. Moreover, further trouble of having “pink-ring” becomes possible. Therefore, the Cu surface of the bonding pad 12 is only treated by performing a “specialized micro-roughening” treatment for achieving surface of having superior adhesion. The roughening process can take be in the form of microabrasion and micro-etching, etc.

With reference to FIG. 4, FIG. 4 is another schematic view showing the semiconductor substrate having enhanced adhesion to semiconductor device according to the present invention. As shown in FIG. 4, the wire bonding pad 16 (covered by the gold electroplating 18 for protection), the wire 20, the bonding pad 12, and the roughening layer 26 (or the passivation layer) formed on the bonding pad 12 remain to be on the surface of the substrate 10. Similarly, when the semiconductor device 24 is packaged onto the substrate 10, the semiconductor device 24 can adhere to the bonding pad 12 using the adhesive 22 so as to complete the electrical connection procedure of the wires 20 (the wire bonding process).

However, the bonding pad 12 is processed by using gold electroplating process to form a gold electroplating section 28, so as to enhance the electrical conductivity of the bonding pad 12, and so that the bonding pad 12, which is adhered to the semiconductor device 24, can be more conductive.

Additionally, on the surface of the substrate 10, at the time of completing the final etching of the wire circuits (etching process of the wire bonding pad), part of the Cu surface is reserved to not being etched, and is covered by the solder mask 12 for retaining part of the Cu surface for forming the bonding pad 12 as shown in FIG. 3 or 4.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A manufacturing method of a semiconductor substrate having enhanced adhesion to a semiconductor device having an electrical node, and the substrate having an internal wire configuration, a wire bonding pad electrically connecting with the internal wire configuration, a wire electrically connecting with the wire bonding pad and the semiconductor device, and a bonding pad adhering to the semiconductor device using an adhesive, wherein the bonding pad is first processed by a roughening treatment or a passivation treatment to form a roughened layer or a passivation layer on the bonding pad.

2. The method as claimed in claim 1, wherein the whole or a part of the bonding pad is processed by the roughening treatment or the passivation treatment to form the roughened layer or the passivation layer on the bonding pad.

3. The method as claimed in claim 1, wherein the bonding pad is of Cu.

4. The method as claimed in claim 1, wherein the passivation treatment on the bonding pad is a brown-oxide treatment or a black-oxide treatment.

5. The method as claimed in claim 4, wherein the bonding pad processed by the brown-oxide treatment or the black-oxide treatment is processed by a plasma treatment.

6. The method as claimed in claim 1, wherein the roughness of the surface of the bonding pad processed by the brown-oxide treatment or the black-oxide treatment is 0.4 to 0.5 μm.

7. The method as claimed in claim 1, wherein the manufacturing method further comprises:
a gold electroplating section, formed on the bonding pad by the electroplating for enhancing the conductivity.
